(19) United States
(12) Patent Application Publication
(10) Pub. No.: US 2009/0189198 A1
(43) Pub. Date: Jul. 30, 2009

(54) STRUCTURES OF SRAM BIT CELLS

(75) Inventor: Katsura Miyashita, Fishkill, NY (US)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 12/020,011

(22) Filed: Jan. 25, 2008

(51) Int. Cl. H01L 29/04; H01L 21/336

(52) U.S. Cl. 257/255; 438/198; 257/E29.004; 257/E21.409

(57) ABSTRACT

An SRAM bit cell structure that can be produced in small sizes while maintaining performance is presented. In one configuration, an SRAM bit cell includes driver field effect transistors that are p-type field effect transistors, load field effect transistors that are n-type field effect transistors and transfer gates that are p-type field effect transistors. Each field effect transistor may be arranged on a substrate that will enhance performance. In one arrangement, the p-type field effect transistors may be arranged on a silicon (110) substrate to enhance hole mobility while the n-type field effect transistors may be arranged on a silicon on insulator (100) substrate to enhance electron mobility. In another arrangement, the load n-type field effect transistor may be arranged on the same silicon (110) substrate as the other field effect transistors in the cell.

### BACKGROUND

Static random access memory (SRAM) cells have occupied a large portion of the Large Scale Integrated (LSI) device chip market as higher volume memory has become a desired feature. However, as further chip developments are made, the chip size is decreasing. In order to remain competitive, SRAM cell size has had to decrease with the decreasing chip size. While it is possible to decrease SRAM cell size, this size reduction leads to performance deficiencies.

In order to maintain performance of the overall SRAM, the performances of its constituent metal-oxide field effect transistors (MOSFETs) must also be maintained. Since a smaller MOSFET generally includes a narrower channel through which charge carriers, such as electrons, can flow, performance of the MOSFET may be reduced by the narrower channel, thereby negatively impacting the performance of its SRAM cell.

### SUMMARY

This summary is provided to introduce a selection of concepts in a simplified form that are further described below in the Detailed Description. This summary is not intended to identify key features or essential features of the claimed subject matter.

There is a need for a SRAM bit cell structure that can be produced in small sizes while maintaining performance. In one configuration, a SRAM bit cell includes driver field effect transistors, load field effect transistors and transfer gates. The driver field effect transistors and transfer gates may be p-type field effect transistors. The load field effect transistors may be n-type field effect transistors. Each field effect transistor may be arranged in and on a layer that will enhance transistor performance. For instance, the p-type field effect transistors may be arranged on a silicon (110) substrate to enhance hole mobility while the n-type field effect transistors may be arranged on a silicon on insulator (100) substrate to enhance electron mobility. To accomplish this, a hybrid orientation technique (HOT) process may be performed on a silicon layer to produce an embedded silicon region having a different crystalline surface orientation than the surrounding silicon layer within the same SRAM cell.

In another configuration, the n-type load field effect transistors may be arranged on the same silicon (110) substrate having a uniform crystalline surface orientation throughout the SRAM cell, as the other field effect transistors. This arrangement may allow for ease of manufacture and produce a structure that may be scaled down even further than an arrangement using a HOT region.

These and other aspects of the disclosure will be apparent upon consideration of the following detailed description of illustrative embodiments.

### BRIEF DESCRIPTION OF THE DRAWINGS

A more complete understanding of the present invention and the potential advantages thereof may be acquired by referring to the following description of illustrative embodiments in consideration of the accompanying drawings, in which like reference numbers indicate like features, and wherein:

FIG. 1 is a circuit diagram of an SRAM bit cell as known in the prior art.

FIG. 2 is a top down image of an SRAM bit cell as known in the prior art.

FIG. 3 is a circuit diagram of an SRAM bit cell according to one illustrative arrangement.

FIG. 4 is a top down image of an SRAM bit cell according to one illustrative arrangement.

FIG. 5 is a top down image of an SRAM bit cell according to another illustrative arrangement.

### DETAILED DESCRIPTION

The various aspects summarized previously may be embodied in various forms. The following description shows by way of illustration of various embodiments and configurations in which the aspects may be practiced. It is understood that the described embodiments are merely examples, and that other embodiments may be utilized and structural and functional modifications may be made, without departing from the scope of the present disclosure.

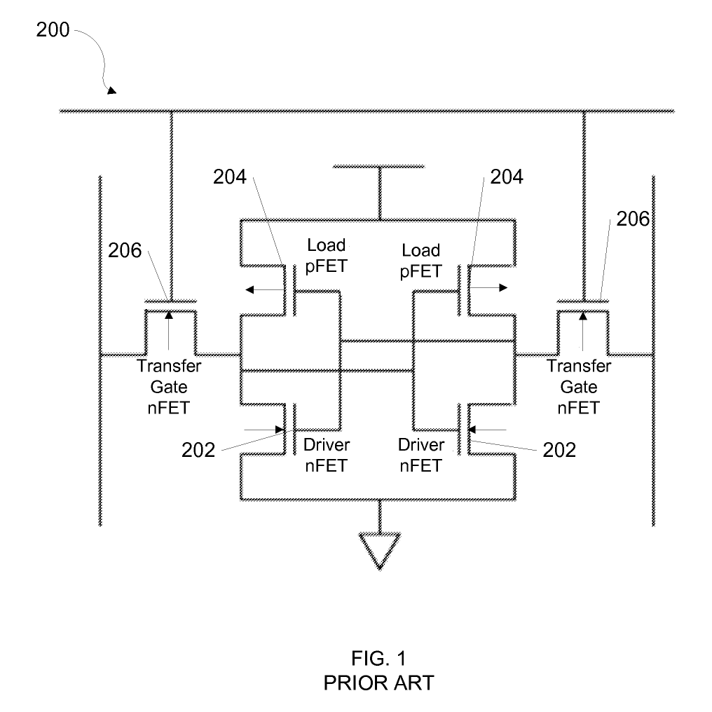

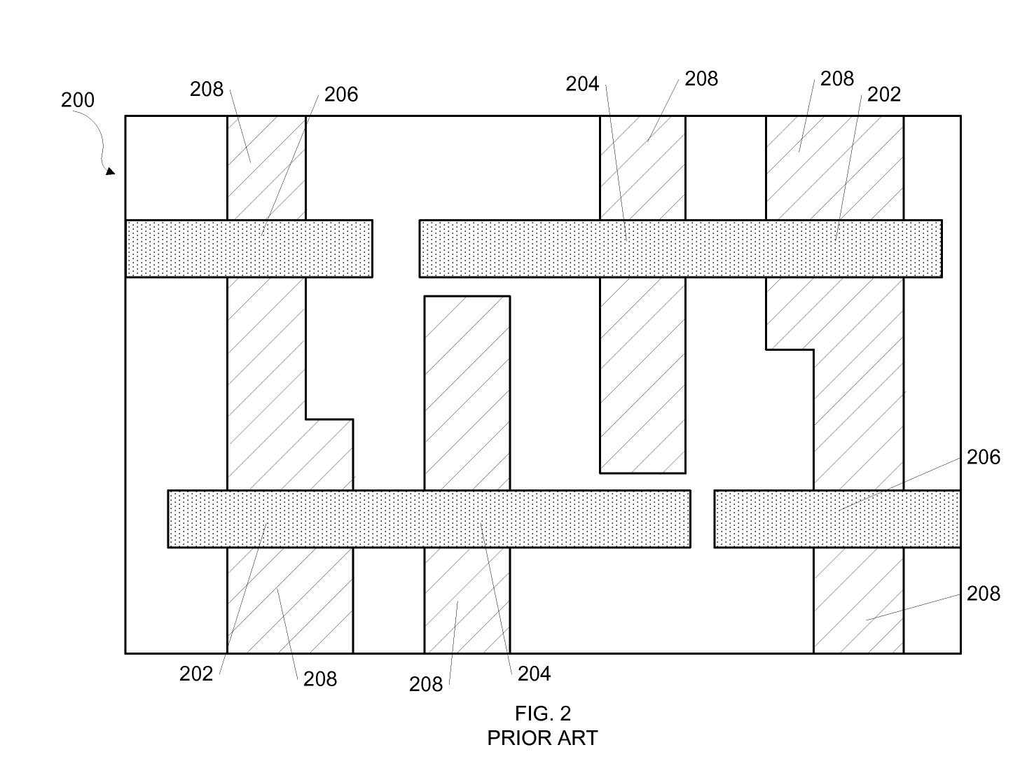

FIG. 1 illustrates a circuit diagram of a conventional six transistor static random access memory (SRAM) bit cell 200. The cell 200 has two driver field effect transistors (FETs) 202 that are n-type FETs (nFETs), two load FETs 204 that are p-type FETs (pFETs) 204 and two transfer gates 206 using nFETs. The same six transistor SRAM cell 200 is shown as a top-down image in FIG. 2. Typically, either a silicon (Si) substrate has been used or a silicon on insulator (SOI) substrate has been used throughout an entire SRAM cell. As shown in FIG. 2, each FET is arranged in and on a Si (100) substrate 208 having a uniform crystalline surface orientation throughout. Each of the different substrates have advantages and disadvantages to being used with nFETs and pFETs. For example, it is generally known that hole mobility on Si (110) substrate is higher than on Si (100) substrate. On the other hand, electron mobility on Si (110) substrate may be lower than that on Si (100).

As SRAM cell size becomes smaller, to accommodate smaller chip sizes, performance may decrease. The smaller size may lead to smaller or narrower channels along which charge carriers can flow. Narrow channels can constrict flow and reduce performance. For instance, as the size decreases, metal-oxide semiconductor field effect transistor (MOSFET) performance may decrease due to the narrow channels. To maintain SRAM performance, MOSFET performance should also be maintained, despite the narrower channels.

However, one may take advantage of the narrower channels to maintain performance. MOSFET performance in SRAM cells is generally affected by compressive stress generated by the surrounding shallow trench isolation (STI) regions. The compressive stress caused by the STI regions may enhance hole mobility in pFETs but degrade electron mobility in nFETs. Accordingly, a narrow channel pFET may show better performance than a narrow channel nFET, due to the relatively increased amount of compressive stress from the STI regions directed into the narrower channels.

Moreover, a hybrid orientation technology (HOT) process may be used to further enhance pFET performance. Use of the HOT process for providing locally-optimized FET regions is known in general. With the HOT process, a silicon-on-oxide wafer is provided wherein the upper silicon layer has a first crystalline surface orientation, such as (100), and the lower silicon layer has a second different crystalline surface orientation, such as (110). Then, a trench is formed in the upper silicon layer extending through the intervening insulating or other oxide layer into the lower silicon layer. Then, bulk silicon is epitaxially grown such that it has the same crystalline surface orientation, in this case 110, as the lower silicon layer. After adjusting the upper surface of the epitaxially grown silicon through chemical-mechanical polishing, a transistor or other device may be formed in the epitaxially-grown silicon region, also referred to herein as a HOT region.

Using the HOT process in an SRAM cell, a Si (110) substrate may be utilized with the pFETs since Si (110) may further improve hole mobility in pFETs, whereas nFETs in the same SRAM cell may use a Si (100) substrate since Si (100) may provide better electron mobility in nFETs than Si (110). Accordingly, the use of the different silicon crystalline surface orientations for each type of FET within an SRAM cell may enhance performance of the SRAM cell, overall.

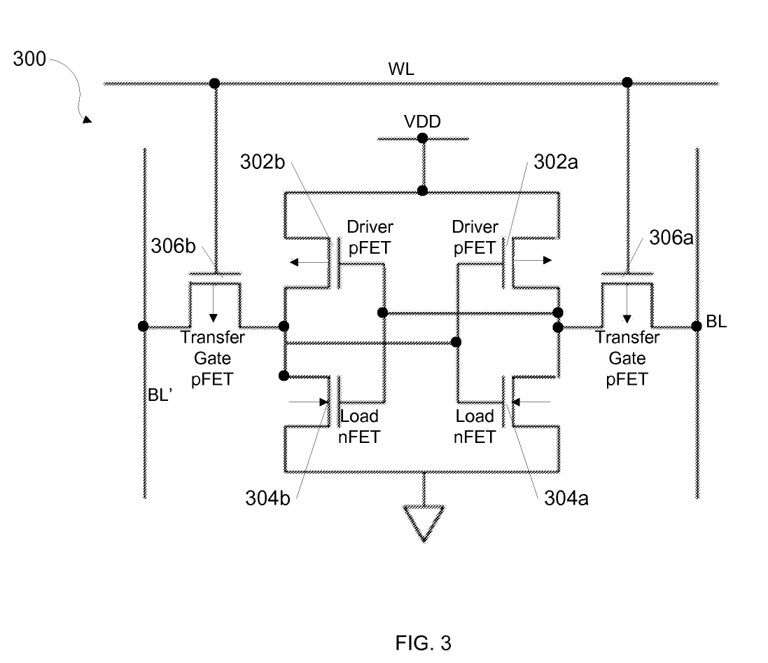

FIG. 3 is a circuit diagram showing the SRAM cell 300 according to aspects of this disclosure. In this arrangement, the transfer gates 306 are pFETs. The use of pFETs as transfer gates 306a, 306b may increase SRAM performance since, as discussed above, pFET performance may be better with a narrow channel than nFET performance. In addition, the functions of the nFETs and pFETs may be opposite of what is used in the conventional SRAM bit cell 200 of FIGS. 1 and 2. For example, in the conventional SRAM bit cell 200, the driver FETs 202 are generally nFETs, while the load FETs 204 are generally pFETs. As shown in FIG. 3, the functions of the pFETs and nFETs may be reversed in this configuration. The SRAM cell 300 may thus include nFETs as the load FETs 304a, 304b, while pFETs act as the driver FETs 302a, 302b.

In the shown embodiment of FIG. 3, transfer gate pFETs 306a and 306b each have a gate coupled to the same word line WL, and each also has a source or a drain coupled to corresponding complementary bit lines BL or BL′. Driver pFETs 302a and 302b each have a source or drain coupled to a fixed power supply voltage VDD. Driver pFET 302a has a gate coupled to the other of the source or drain of pFET 306b, and driver pFET 302b has a gate coupled to the other of the source or drain of pFET 306a. Load pFETs 304a and 304b each have a source or drain coupled to a fixed ground voltage. Load pFET 304a has a gate coupled to the gate of driver pFET 302a, and load pFET 304b has a gate coupled to the gate of driver pFET 302b.

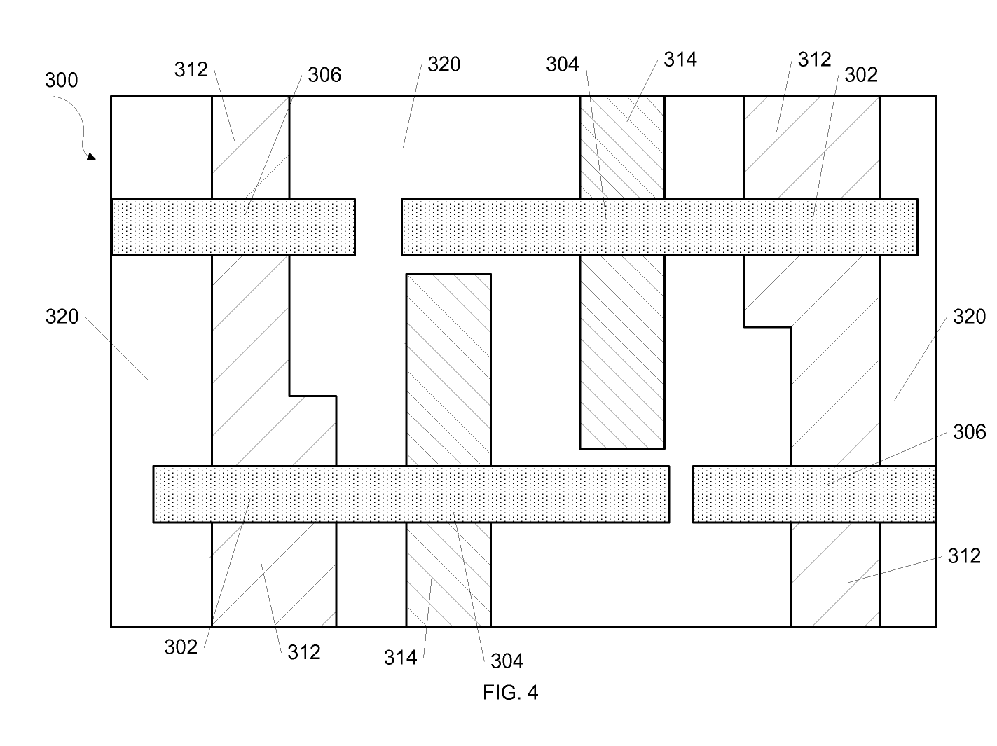

FIG. 4 illustrates one example of this SRAM bit cell 300 structure. Transfer pFETs 306 and driver pFETs 302 are arranged in and on an epitaxially-grown bulk Si (110) layer 312. This arrangement may allow for higher hole mobility due to the compressive stress caused by the surrounding STI layer 320. In addition, the load nFETs 304 are arranged in and on a SOI (100) structure 314 to maintain nFET performance and to realize this structure since the required crystal surface is different from that of a pFET. This arrangement may enhance performance by taking advantage of the performance characteristics of each type of FET and the substrate on which it may be arranged. It should be noted that, if the nFETs in the conventional structure of FIG. 2 were attempted to be arranged on an SOI (100) structure, then this would decrease cell stability since the body potential of the nFET transfer gates 206 would be floating. In contrast, the arrangement of FIG. 4 may result in a more stable SRAM bit cell since SOI (100) and bulk Si (110) are both used yet without the problem of floating body potentials of the transfer pFETs 306. Thus, the performance of the pFETs may be increased, thereby improving the beta ratio and stability of the SRAM cell. The increased stability may further improve SRAM performance.

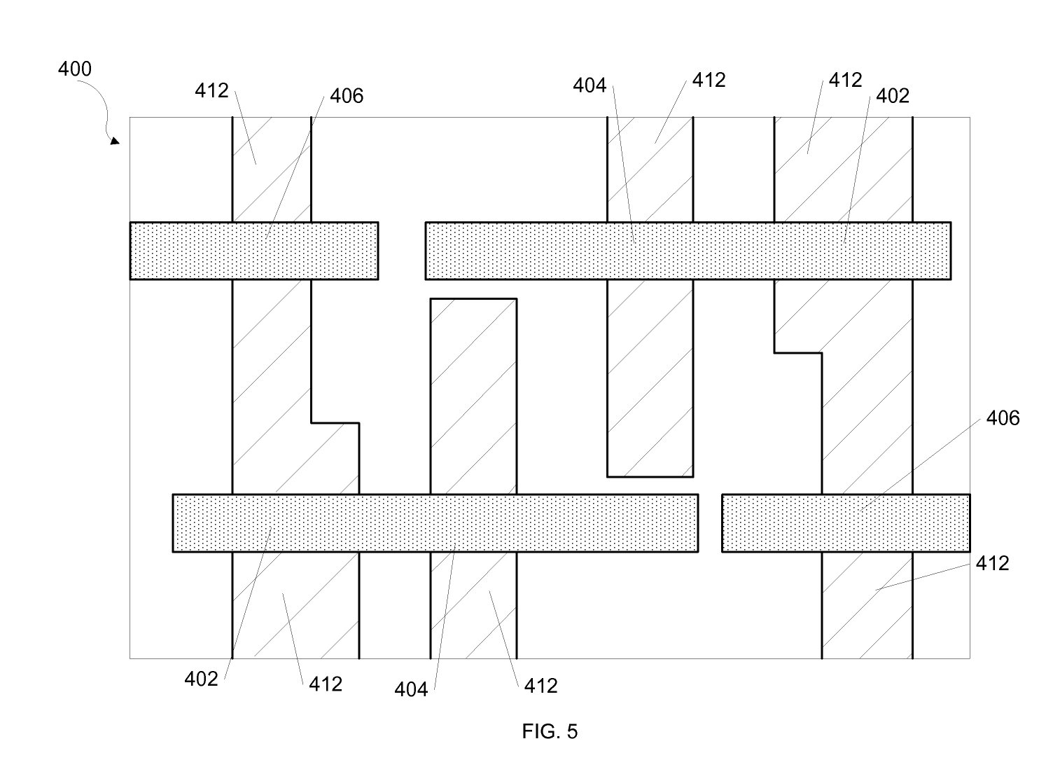

FIG. 5 illustrates another configuration of this SRAM bit cell 400 structure. In this configuration, the transfer gates 406 and driver FETs 402 are again pFETs. The pFETs may be arranged in and on a Si (110) 412 substrate to enhance performance through narrow FET channels. The load FETs 404 are nFETs, which may also be arranged in and on the same Si (110) substrate 412. Although nFET on Si (110) may show lower Ion than if it were disposed on Si (100), this arrangement may be used when SRAM size is more important than the performance of the nFET in the SRAM bit cell. This arrangement provides for ease of manufacturing and may be scaled down to even smaller dimensions than the configuration of FIG. 4.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. Numerous other embodiments, modifications and variations within the scope and spirit of the appended claims will occur to persons of ordinary skill in the art from a review of this disclosure.

What is claimed is:

1. A semiconductor device, comprising:
a plurality of static random access memory bit cells, each bit cell including:
a pair of driver field effect transistors, the driver field effect transistors being p-type field effect transistors;
a pair of load field effect transistors, the load field effect transistors being n-type field effect transistors; and
a pair of transfer field effect transistors, the transfer field effect transistors being p-type field effect transistors.

2. The memory device of claim 1, further including a first silicon layer with a (110) crystalline surface orientation, wherein the driver p-type field effect transistors are disposed in and on the silicon layer.

3. The memory device of claim 2, wherein the transfer p-type field effect transistors are also disposed in and on the first silicon layer.

4. The memory device of claim 3, wherein the load n-type field effect transistors are also disposed in and on the first silicon layer.

5. The memory device of claim 3, further including a second silicon layer embedded in the first silicon layer, wherein the second silicon layer has a crystalline surface orientation of (100) and the load n-type field effect transistors are disposed in and on the second silicon layer.

6. A method of manufacturing a semiconductor device, comprising the steps of:
providing a first silicon layer disposed on an insulating layer, the first silicon layer having a (100) crystalline surface orientation; and
forming a plurality of static random access memory bit cells, including, for each bit cell:
forming a pair of trenches in the first silicon layer,
epitaxially growing a bulk silicon region having a (110) crystalline surface orientation in each of the trenches,
forming a pair of driver field effect transistors in and on one of the epitaxially grown silicon regions, the driver field effect transistors each being a p-type field effect transistor,
forming a pair of load field effect transistors in and on the first silicon layer, the load field effect transistors each being an n-type field effect transistor, and
forming a transfer gate field effect transistor in and on the other of the epitaxially grown silicon regions, the transfer gate field effect transistors being p-type field effect transistors.

7. A semiconductor device, comprising a plurality of static random access memory bit cells, each bit cell including a first pFET having one of a source or a drain coupled to a first bit line, and having a gate coupled to a word line.

8. The semiconductor device of claim 7, wherein each bit cell further includes a second pFET having one of a source or a drain coupled to a second bit line, and having a gate coupled to the word line.

9. The semiconductor device of claim 8, wherein each bit cell further includes a third pFET having a gate coupled to the other one of the source or the drain of the first pFET and a fourth pFET having a gate coupled to the other one of the source or the drain of the second pFET.

10. The semiconductor device of claim 9, wherein each bit cell further includes a first nFET having a gate coupled to the gate of the third pFET and a second nFET having a gate coupled to the gate of the fourth pFET.

11. The semiconductor device of claim 10, further including:
a first silicon layer having a crystalline surface orientation of (110), wherein the first, second, third, and fourth pFETs are each disposed in and on the silicon layer; and
a second silicon layer having a crystalline surface orientation of (100), wherein the first and second nFETs are each disposed in and on the second silicon layer.

12. The semiconductor device of claim 11, wherein the second silicon layer is embedded in the first silicon layer.

13. The semiconductor device of claim 10, further including a first silicon layer having a crystalline surface orientation of (110), wherein the first, second, third, and fourth pFETs, and the first and second nFETs, are each disposed in and on the silicon layer.

14. The semiconductor device of claim 7, further including a silicon layer having a crystalline surface orientation of (110), wherein the first pFET is disposed in and on the silicon layer.
